(19) United States
(12) Patent Application Publication
(10) Pub. No.: US 2010/0002492 A1
(43) Pub. Date: Jan. 7, 2010

(54) RESISTANCE CHANGE MEMORY

(75) Inventor: Takeshi KAJIYAMA, Yokohama-shi (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/497,613

(22) Filed: Jul. 3, 2009

(30) Foreign Application Priority Data
Jul. 3, 2008 (JP) 2008-174925

(51) Int. Cl. G11C 11/00; G11C 11/14

(52) U.S. Cl. 365/148; 365/171

(57) ABSTRACT

A resistance change type memory includes a first device region and first and second bit lines provided above the first device region and along a first direction. First and second resistance change elements are connected to the first and second bit lines, respectively. A first transistor is serially connected to both the first and second resistance change elements, formed in the first device region, and has a first gate electrode extending along a second direction which intersects with the first direction. The first gate electrode has a gate width equal to a width in the second direction of the first device region.

### CROSS-REFERENCE TO RELATED APPLICATIONS

This application is based upon and claims the benefit of priority from prior Japanese Patent Application No. 2008-174925, filed Jul. 3, 2008, the entire contents of which are incorporated herein by reference.

### BACKGROUND OF THE INVENTION

1. Field of the Invention

The present invention relates to the resistance change memories which have resistance change elements and cell transistors.

2. Description of the Related Art

When resistance change memories such as spin injection magnetoresistive random access memory (MRAM) requires a large switching current for writing, the magnitude of the current depends on the gate width (Tr-W) of a transistor of a cell selection switch. The gate width of the transistor in turn determines the cell area. For this reason, it has been difficult to realize reduced cell area and increased write current.

### BRIEF SUMMARY OF THE INVENTION

According to an aspect of the present invention, there is provided a resistance change type memory comprising: a first device region; a first bit line and a second bit lines both provided above the first device region and along a first direction; a first resistance change element and a second resistance change element connected to the first and second bit lines, respectively; and a first transistor serially connected to both the first and second resistance change elements, formed in the first device region, and having a first gate electrode extending along a second direction which intersects with the first direction, the first gate electrode having a gate width equal to a width in the second direction of the first device region.

### BRIEF DESCRIPTION OF THE SEVERAL VIEWS OF THE DRAWING

FIG. 1 illustrates a layout of the magnetic random access memory according to a first embodiment of the present invention.

FIG. 2 illustrates the cross-sectional view taken along line II-II of FIG. 1.

FIG. 3 illustrates the cross-sectional view taken along line III-III of FIG. 1.

FIG. 4 illustrates the cross-sectional view taken along line IV-IV of FIG. 1.

FIG. 5 illustrates the circuit diagram of four cells of the magnetic random access memory according to the first embodiment.

FIG. 6 illustrates writing operation by the magnetic random access memory according to the first embodiment.

FIG. 7 illustrates a layout of the magnetic random access memory of a second embodiment of the present invention.

FIG. 8 illustrates a layout of the magnetic random access memory of a third embodiment of the present invention.

### DETAILED DESCRIPTION OF THE INVENTION

Embodiments of the present invention will be described below, with a magnetic random access memory used as an example of a resistance change memory. In the description below, the same reference number is given to the same component across all drawings.

### [1] First Embodiment

[1-1] Layout

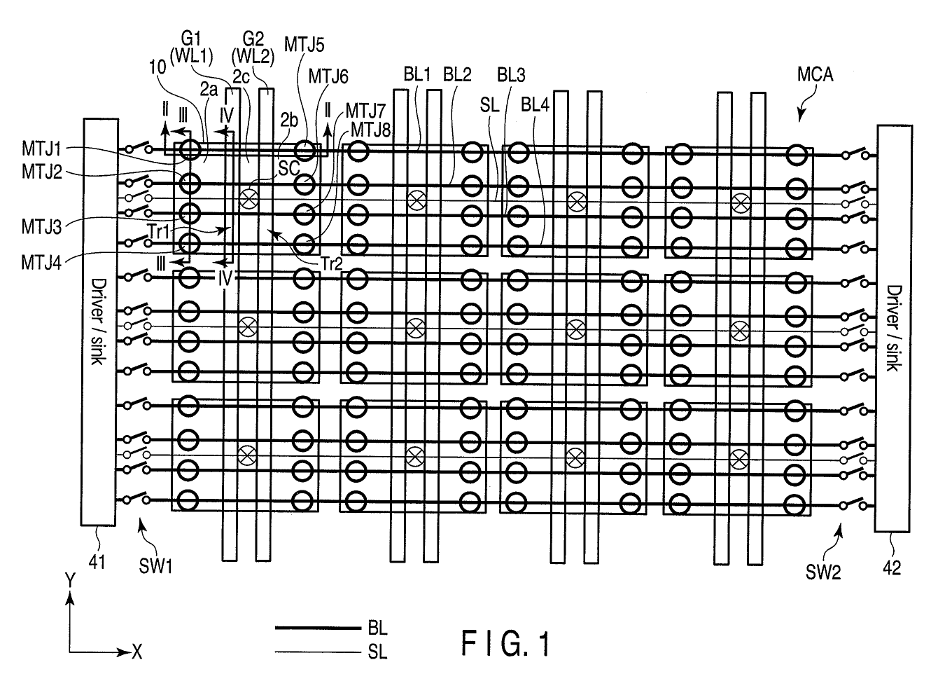

Referring to FIG. 1, the layout of the magnetic random access memory according to the first embodiment of the present invention will be described. The detailed description will be given of a device region in the upper-left portion of the drawing.

As shown in FIG. 1, island shaped device regions 10 are formed. MTJ elements MTJ1, MTJ2, MTJ3, MTJ4, MTJ5, MTJ6, MTJ7, and MTJ8 are provided above one device region 10, forming eight cells in the device region 10. MTJ elements MTJ1, MTJ2, MTJ3, and MTJ4 are arranged in a line along the Y direction near the left end of the X direction of device region 10. MTJ elements MTJ5, MTJ6, MTJ7, and MTJ8 are arranged in a line along the Y direction in near right end of the X direction of device region 10.

Bit lines BL1, BL2, BL3, and BL4 run along the X direction above device region 10. Bit line BL1 is provided above MTJ elements MTJ1 and MTJ5, and is connected to MTJ elements MTJ1 and MTJ5. Bit line BL2 is provided above MTJ elements MTJ2 and MTJ6, and is connected to MTJ elements MTJ2 and MTJ6. Bit line BL3 is provided above MTJ elements MTJ3 and MTJ7, and is connected to MTJ elements MTJ3 and MTJ7. Bit line BL4 is provided above MTJ elements MTJ4 and MTJ8, and is connected to MTJ elements MTJ4 and MTJ8.

Gate electrodes G1 and G2 (word lines WL1 and WL2) run along the Y direction above device region 10. Source/drain diffusion area 2a is formed in device region 10 on the left-hand side of gate electrode G1. Source/drain diffusion area 2b is formed in device region 10 on the right-hand side of gate electrode G2. Source/drain diffusion area 2c is formed in device region 10 between gate electrodes G1 and G2. As a result, two transistors Tr1 and Tr2 are formed in device region 10. That is, transistor Tr1 consists of gate electrode G1 and source/drain diffusion areas 2a and 2c, and transistor Tr2 consists of gate electrode G2 and source/drain diffusion areas 2b and 2c.

Source line SL runs along the X direction above device region 10. Source line SL is provided between bit lines BL2 and BL3 which are positioned in the center of device region 10, and is shared by all MTJ elements MTJ1, MTJ2, MTJ3, MTJ4, MTJ5, MTJ6, MTJ7, and MTJ8 in device region 10 in question. Source line SL is connected to source line contact SC. Source line contact SC is arranged between bit lines BL2 and BL3 and between gate electrodes G1 and G2, and is connected to source/drain diffusion area 2c, which is shared by transistors Tr1 and Tr2.

Both ends of each bit line BL1, BL2, BL3, and BL4 and those of source line SL are connected to switches SW1 and SW2 in the periphery of memory cell array MCA. Switches SW1 and SW2 are connected to driver/sinks 41 and 42, respectively.

Thus, one source contact SC of the present embodiment is connected eight cells with four of the eight cells at the right-hand side of source contact SC and remaining four cells at the left side of it. In addition, the four cells at the left-hand side share one transistor, and the four cells at the right side share one transistor. That is, transistor Tr1 is shared by MTJ elements MTJ1, MTJ2, MTJ3, and MTJ4 which constitute the four cells on the left-hand side of source line contact SC, and transistor Tr2 is shared by MTJ elements MTJ5, MTJ6, MTJ7, and MTJ8 which constitute the four cells on the right-hand side of source line contact SC. Therefore, device region 10 of each cell of four cells which share one transistor and are arranged in a line along the Y direction are not separate in present embodiment. In other words, the gate width (width in the Y direction) of each gate electrode G1 and G2 on device region 10 is equal to the width of device region 10 in the Y direction.

Note that all cells in one device region 10 (eight cells in the present embodiment) share one sense amplifier (not shown). That is, one sense amplifier is provided in the peripheral circuit area for one island shaped device region 10.

[1-2] Cross-Sectional Structure

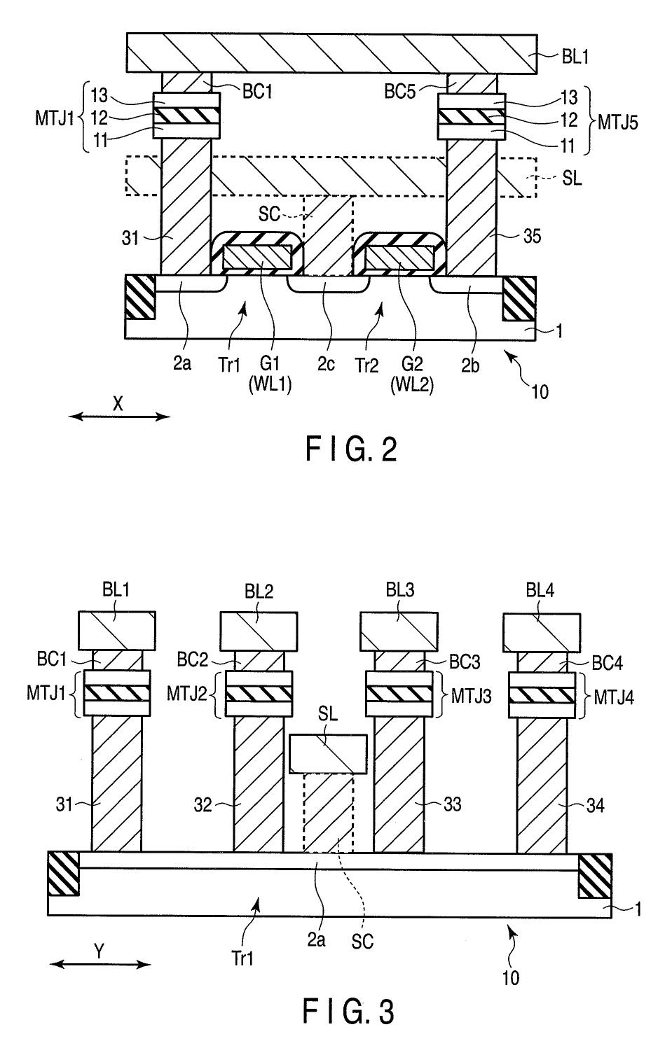

First, referring to FIG. 2, description will be given of a cross-sectional structure of the memory cell taken along line II-II of FIG. 1. As shown in FIG. 2, gate electrodes G1 and G2 are formed above semiconductor substrate 1. In semiconductor substrate 1 at sides of gate electrodes G1 and G2, source/drain diffusion areas 2a, 2b, and 2c are formed. As a result, two transistors Tr1 and Tr2 are formed in device region 10. Source/drain diffusion area 2a is connected to MTJ element MTJ1 via contact 31, and MTJ element MTJ1 is connected to bit line BL1 via bit line contact BC1. Source/drain diffusion area 2b is connected to MTJ element MTJ5 via contact 35, and MTJ element MTJ5 is connected to bit line BL1 via bit line contact BC5. Source/drain diffusion area 2c is connected to source line SL via source line contact SC. Each MTJ element MTJ1 and MTJ5 has fixed layer (pin layer) 11, recording layer (free layer) 13, and tunnel insulating layer 12 sandwiched therebetween.

Next, referring to FIG. 3, description will be given of the cross-sectional structure of the memory cell taken along line III-III of FIG. 1. As shown in FIG. 3, one source/drain diffusion area 2a of transistor Tr1 is connected to four MTJ elements MTJ1, MTJ2, MTJ3, and MTJ4. That is, four MTJ elements MTJ1, MTJ2, MTJ3, and MTJ4 share one transistor Tr1. A pitch between each pair of adjacent bit lines BL1, BL2, BL3, and BL4 is the same, and source line SL is provided between bit lines BL2 and BL3. Therefore, the pitch between source line SL and bit line BL2 and the pitch between source line SL and bit line BL3 are narrower than each pitch between adjacent bit lines BL1, BL2, BL3, and BL4.

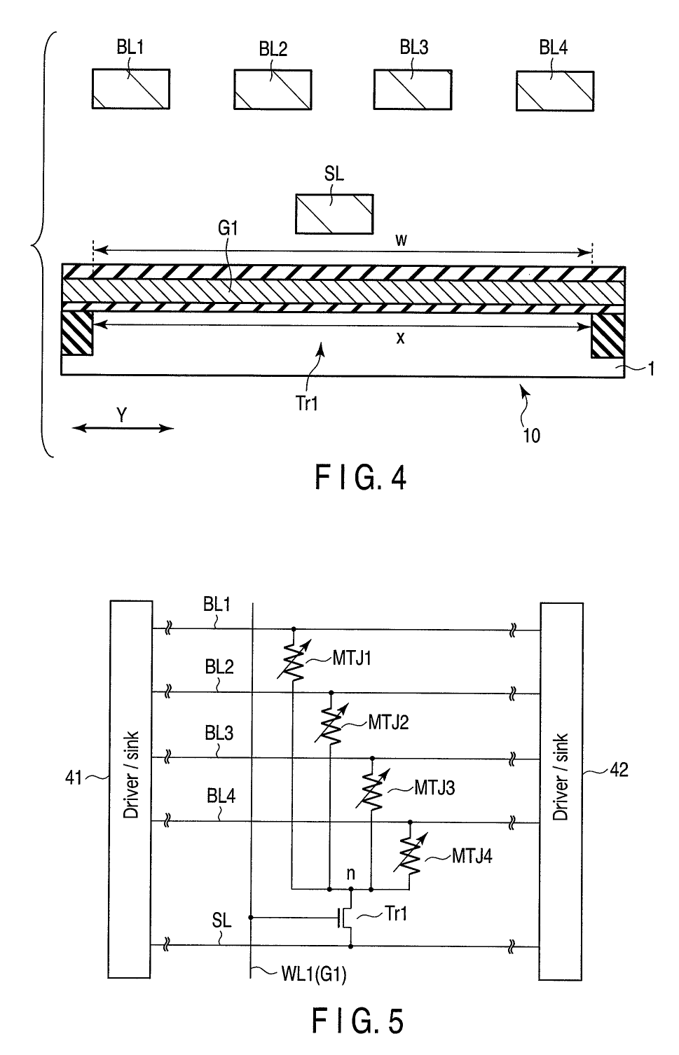

Next, referring to FIG. 4, description will be given of the cross-sectional structure of the memory cell taken along line IV-IV of FIG. 1. As shown in FIG. 4, gate electrode G1 of transistor Tr1 runs along the Y direction above device region 10 and below four bit lines BL1, BL2, BL3, and BL4. The channel region of gate electrode G1 is not divided along the Y direction in device region 10. Therefore, the gate width W of gate electrode G1 is equal to the width X of device region 10 in the Y direction.

[1-3] Circuit Composition

Referring to FIG. 5, description will be given of the circuit configuration of four cells of the magnetic random access memory according to the first embodiment. Note that the detailed description will be given of four cells on the left-hand side of device region 10 in the upper-left portion of FIG. 1.

As shown in FIG. 5, one end of each of the MTJ elements MTJ1, MTJ2, MTJ3, and MTJ4 is connected to bit lines BL1, BL2, BL3, and BL4, respectively. The other end of each of the MTJ elements MTJ1, MTJ2, MTJ3, and MTJ4 is connected to common node n. Node n is connected to one end of the current path of transistor Tr1, and the other end of the current path is connected to source line SL. Gate electrode G1 of transistor Tr1 is connected to word line WL1.

Thus, four MTJ elements MTJ1, MTJ2, MTJ3, and MTJ4 respectively use four bit lines BL1, BL2, BL3, and BL4, and they share one transistor Tr1 and one source line SL in the present embodiment.

[1-4] Writing

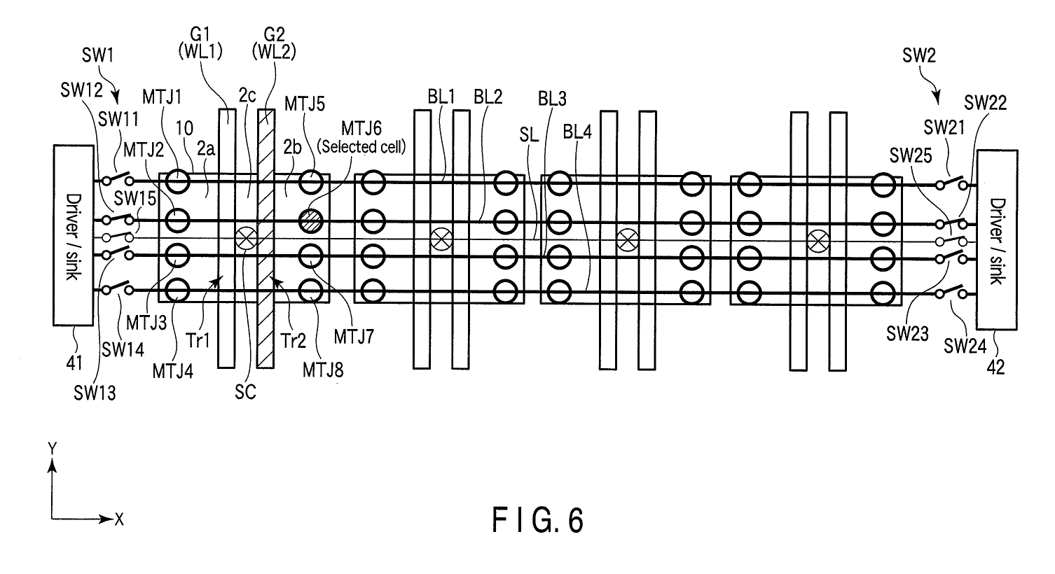

Referring to FIG. 6, description will be given of write operation by the magnetic random access memory of the first embodiment. Note that the detailed description will be given of an example where MTJ element MTJ5 is the selected cell to which writing is performed through the spin injection.

First, gate electrode G2 is selected, then switches SW12 and SW22 of the ends of bit line BL2 which is connected to the selected MTJ element MTJ5 are turned on, and switches SW15 and SW25 of the ends of source line SL are also turned on. As a result, write current flows from or to source line SL to or from bit line BL2. Specifically, the current flow through source line SL, source line contact SC, source/drain diffusion area 2c, source/drain diffusion area 2b, MTJ element MTJ6, and bit line BL2 in the mentioned order, or it flows through bit line BL2, MTJ element MTJ6, source/drain diffusion area 2b, source/drain diffusion area 2c, source line contact SC, and source line SL in the mentioned order.

The direction in which write current flows depends on data to be written in a selected cell. For example, electron flow is passed towards recording layer 13 from fixed layer 11 in order to turn the magnetization of recording layer 13 in antiparallel state to that of fixed layer 11 into parallel state to it. That is, write current is sent towards fixed area 11 from recording layer 13. The resulting state where magnetization of recode layer 13 and that of fixed layer 11 are in the parallel state (forming the low-resistance state) is defined, for example, as the “0” state.

In contrast, electron flow is passed towards fixed layer 11 from recording layer 13 in order to turn the magnetization of recording layer 13 in parallel state to that of fixed layer 11 into antiparallel state to it. That is, write current is sent towards recording layer 13 from fixed layer 11. The resulting state where the magnetization of recording layer 13 and that of fixed layer 11 are in the antiparallel state (forming the high-resistance state) is defined, for example, as the “1” state.

Such a write operation forms a state where three cells (MTJ5, MTJ7, and MTJ8) are also connected to common transistor Tr2. However, bit line selection switches SW11, SW13, SW14, SW21, SW23, and SW24 at ends of bit lines which are connected to these cells stay off, and therefore are in the floating state. For this reason, the write current for MTJ elements MTJ6 does not flow into MTJ elements MTJ5, MTJ7, and MTJ8.

Note that, during writing operation, switches SW1 and SW2 which are connected to non-selected cells and are connected to a shared transistor may not necessarily be all turned off, but may be grounded. Moreover, all switches SW1 and SW2 connected to cells which are not connected to a common transistor may be turned off, of may be grounded.

[1-5] Reading

The present embodiment uses the magnetoresistive effect for reading.

The bit line and word line for a selected cell are selected, and the transistor of the selected cell is turned on. And read current is conducted through the selected MTJ element. The resistance of the MTJ element is read based on this read current, and the resistance is amplified by a sense amplifier to distinguish whether the recorded state is “0” or “1”.

Note that, reading may be based on current measurement read from the selected MTJ element through applying constant voltage, or voltage measurement read from it through applying constant voltage.

[1-6] Advantages

According to the first embodiment, four cells arranged in a line along the gate width direction of a cell transistor share this cell transistor. Therefore, a cell transistor is not formed of the minimum processing size (future size) F as is in the prior art, but of 4F. For this reason, the cell transistor of the present embodiment can have four times long as the conventional cell gate width. That is, the gate width of a cell transistor can be increased by the summed pitch of cells which share one cell transistor. Thereby, it is possible to increase the write current, which will be restricted with the gate width of a cell transistor. Therefore, larger writing current can flow through cells.

Moreover, device regions of cells arranged along the gate width direction of the prior-art cell transistor are separated by element separation regions. In contrast, in present embodiment, device regions of four cells located along the gate width direction of a cell transistor are united to be one. For this reason, present embodiment can maintain the conventional cell area.

Thus, the present embodiment can realize a larger cell transistor gate width even in the spin injection magnetic random access memory which requires a large write current. More than one cell shares this cell transistor, then the write current can be increased while avoiding increase of a cell area.

### [2] The second Embodiment

In the first embodiment, all pitches between each pair of adjacent bit lines, which run along X direction, are equal, and since the source line is arranged among such bit lines, pitch between a bit line and a source line is narrow. In contrast, pitches between each pair of adjacent bit line and source line, which run along X direction, have the same value.

[2-1] Layout

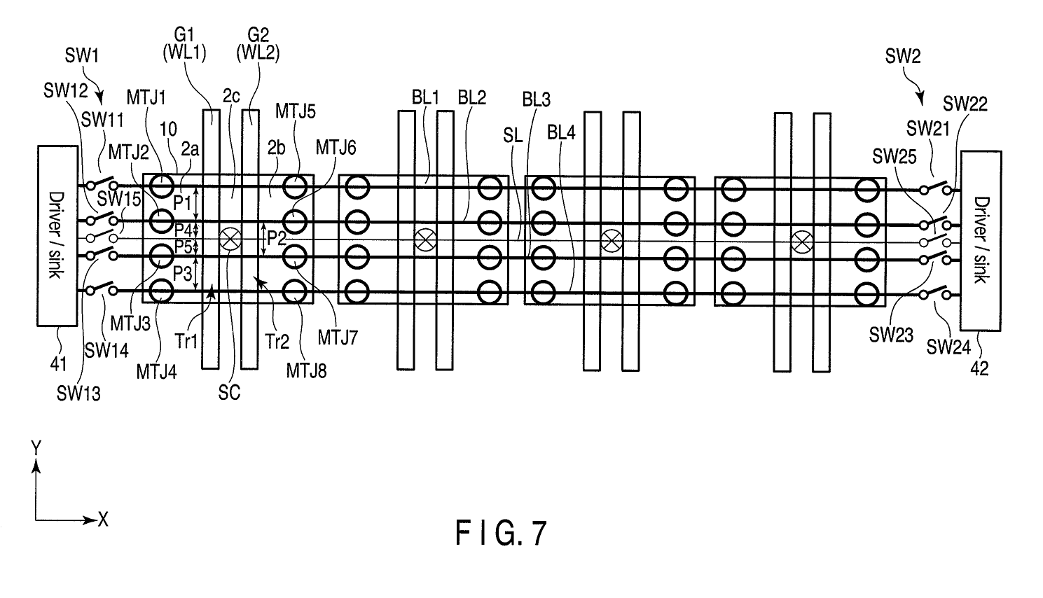

Referring to FIG. 7, the layout of the magnetic random access memory according to the second embodiment of the present invention will be described.

As shown in FIG. 7, the difference between the second and first embodiments lies in the wider pitch P2 between bit lines BL2 and BL3 than pitch P1 between bit lines BL1 and BL2, and pitch P3 between bit lines BL3 and BL4. As a result, in the second embodiment, pitch P4 between bit line BL2 and source line SL and pitch P5 between bit line BL3 and source line SL are larger than those in the first embodiment. Pitches P4 and P5 may be narrower than, wider than, or equal to pitches P1 and P3.

[2-2] Advantages

The second embodiment can realize the same advantages as the first embodiment. Further, the large pitch between two bit lines sandwiching a source line SL can easily form source line contact CS in the second embodiment. Moreover, bit lines and source lines can be provided in the same layer, enabling them to be formed by the same process at the same time.

### [3] The Third Embodiment

The first embodiment connects source line contacts adjacent to each other along the X direction to the same source line, therefore all source line contacts located in a line along the X direction are connected to the same source line. In contrast, the third embodiment connects source line contacts adjacent to each other along the X direction to different source lines, resulting in decreased number of contacts connected to one source line contact.

[3-1] Layout

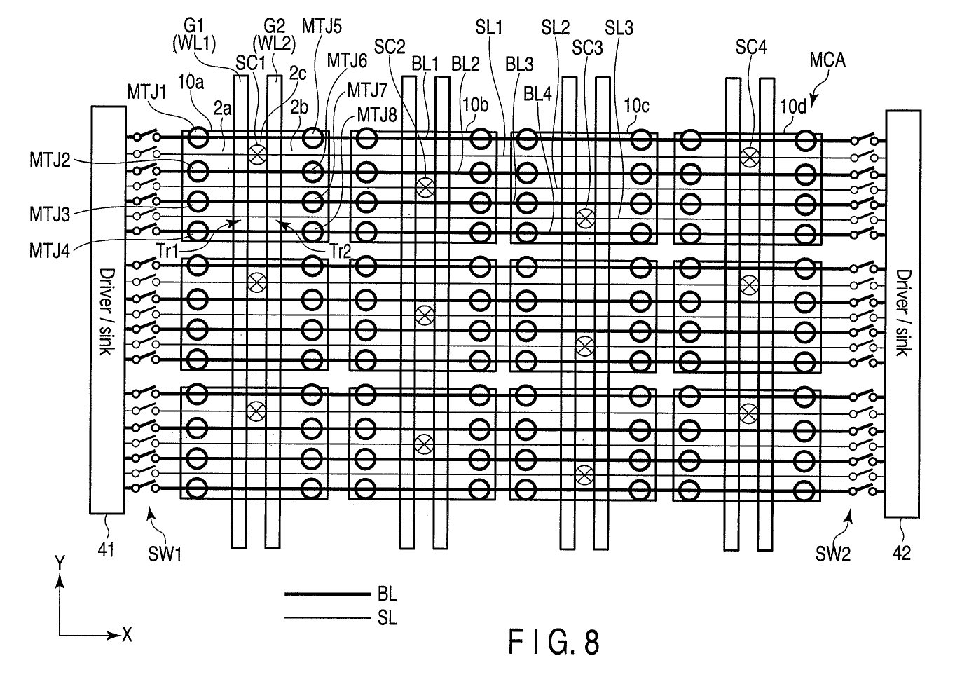

Referring to FIG. 8, the layout of the magnetic random access memory according to the third embodiment of the present invention will be described. The detailed description will be given of a device region in the upper portion of the drawing.

As shown in FIG. 8, the difference between the third and first embodiments lies in that source line contacts SC1, SC2, SC3, and SC4, which are in line along the X direction, are provided at intervals of one-third pitch.

More specifically, source line SL1 is connected to source line contact SC1 in device region 10a and source line contact SC4 in device region 10d, and it is not connected to source line contact SC2 in device region 10b and source line contact SC3 in device region 10c. Source line contact SC2 in device region 10b is connected to source line SL2, and source line contact SC3 in device region 10c is connected to source line SL3.

In other words, source lines SL1, SL2, and SL3 are provided by on-pitch as are bit lines BL1, BL2, BL3, and BL4. Therefore, source line SL1 is provided between bit lines BL1 and BL2, source line SL2 between bit lines BL2 and BL3, and source line SL3 between bit lines BL3 and BL4. And source line contact SC1 is provided under source line SL1 in device region 10a, source line contact SC2 under source line SL2 in device region 10b, and source line contact SC3 under source line SL3 in device region 10c, and source line contact SC4 under source line SL1 in device region 10d.

Note that the reason why the source line contacts are provided at intervals of one-third pitch in present embodiment is utilization of pitches of intervals between two of four cells which are connected to one transistor. That is, the present embodiment sets the pitch of source line contacts to 1/(number of one-transistor-sharing cells minus one). However, it is not limited to one-third pitch, and another pitch, such as one-fourth pitch, maybe used.

[3-2] Advantages

The third embodiment can realize the same advantages as the first embodiment. Further, source line contacts provided at intervals of one-third pitch along the X direction can reduce parasitic capacitance of one source line.

The present invention is not limited above-mentioned embodiments, and may be variously modified in practical application without departing from the sprit of it.

For example, although the embodiments are described for a magnetic random access memory as an example of resistance change memories, they are not limited to this and may be applied to a phase-change random access memory (PRAM) which uses chalcogenide or to a resistive random access memory (ReRAM) which uses strongly correlated electron system material, etc.

Moreover, although four cells share one cell transistor in the embodiments, the number of cells which share one transistor is not limited to this and may be changed.

In addition, the embodiments include various inventions, which can be realized by appropriate combination of some of elements disclosed herein. More particular, a specific configuration composed of only some of all elements illustrated in embodiments can be extracted as distinct invention as long as it can solve the problem to be solved described above and realize advantages illustrated herein.

Additional advantages and modifications will readily occur to those skilled in the art. Therefore and the invention in its broader aspects is not limited to the specific details and representative embodiments shown and described herein. Accordingly and various modifications may be made without departing from the spirit or scope of the general inventive concept as defined by the appended claims and their equivalents.

What is claimed is:

1. A resistance change type memory comprising:
a first device region;
a first bit line and a second bit line both provided above the first device region and along a first direction;
a first resistance change element and a second resistance change element connected to the first and second bit lines, respectively; and
a first transistor serially connected to both the first and second resistance change elements, formed in the first device region, and having a first gate electrode extending along a second direction which intersects with the first direction, the first gate electrode having a gate width equal to a width in the second direction of the first device region.

2. The resistance change type memory according to claim 1, further comprising:
a third resistance change element and a fourth resistance change element connected to the first and second bit lines, respectively; and
a second transistor serially connected to both the third and fourth resistance change elements, formed in the first device region, and having a second gate electrode extending along the second direction, the second gate electrode having a gate width equal to the width in the second direction of the first device region.

3. The resistance change type memory according to claim 2, wherein a source/drain diffusion layer of the first transistor and a source/drain diffusion layer of the second transistor are the same source/drain diffusion layer.

4. The resistance change type memory according to claim 1, further comprising:
a first switch and a second switch each connected to an end of the first bit line; and
a third switch and a fourth switch each connected to an end of the second bit line.

5. The resistance change type memory according to claim 1, wherein all cells in the first device region share one sense amplifier.

6. The resistance change type memory according to claim 1, further comprising:
bit lines including the first and second bit lines and extending along the first direction;
resistance change elements including the first and second resistance change elements and each connected to one of the bit lines; and
a source line shared by resistance change elements provided in the first device region and extending along the first direction.

7. The resistance change type memory according to claim 6, wherein the source line is arranged in the middle of an array of the bit lines.

8. The resistance change type memory according to claim 1, further comprising:
a source line extending along the first direction and between the first and second bit lines, and wherein
a pitch between the second bit line and the source line is narrower than a pitch between the first and second bit lines.

9. The resistance change type memory according to claim 1, further comprising:
a source line extending along the first direction and between the first and second bit lines, and wherein
a pitch between the second bit line and the source line is equal to a pitch between the first and second bit lines.

10. The resistance change type memory according to claim 9, wherein the first and second bit lines are provided in a same interconnect level.

11. The resistance change type memory according to claim 1, further comprising:
a second device region provided adjacent to the first device region along the first direction;
a source line extending along the first direction;
a first source line contact provided below the source line and in the first device region, and connected to the source line; and
a second source line contact provided below the source line and in the second device region, and connected to the source line.

12. The resistance change type memory according to claim 1, further comprising:
a second device region provided adjacent to the first device region along the first direction;
a first source line extending along the first direction and between the first and second bit lines;
a second source line extending along the first direction, the first and second source lines sandwiching the second bit line;
a first source line contact provided below the first source line and in the first device region, and connected to the first source line; and
a second source line contact provided below the second source line and in the second device region, and connected to the second source line.

13. The resistance change type memory according to claim 1, further comprising:
device regions including the first device region and provided in line along the first direction; and
source line contacts each provided in one of the device regions, a pitch between two of the source line contacts in the first direction being 1/(number of one-transistor-sharing cells minus one).

14. The resistance change type memory according to claim 13, further comprising:
bit lines including the first and second bit lines and extending along the first direction; and
source lines extending along the first direction and each provided between two bit lines.

15. The resistance change type memory according to claim 1, further comprising:
a first switch connected to an end of the first bit line; and
a second switch connected to an end of the second bit line, and wherein
the first switch is turned on and second switch is turned off on writing data into the resistance change element.

16. The resistance change type memory according to claim 1, wherein the resistance change type memory is a spin injection type magnetic random access memory.
